(19) United States
(12) Patent Application Publication
(10) Pub. No.: US 2021/0294007 A1
(43) Pub. Date: Sep. 23, 2021

(54) COLOR FILM SUBSTRATE, MANUFACTURING METHOD OF THE SAME, DISPLAY PANEL AND DISPLAY DEVICE

(71) Applicants: BEIJING BOE OPTOELECTRONICS TECHNOLOGY CO., LTD., Beijing (CN); BOE TECHNOLOGY GROUP CO., LTD., Beijing (CN)

(72) Inventors: Lin HAN, Beijing (CN); Chunlei WANG, Beijing (CN); Kun JIANG, Beijing (CN); Na LI, Beijing (CN)

(73) Assignees: BEIJING BOE OPTOELECTRONICS TECHNOLOGY CO., LTD., Beijing (CN); BOE TECHNOLOGY GROUP CO., LTD., Beijing (CN)

(21) Appl. No.: 16/619,822

(22) PCT Filed: Mar. 25, 2019
(86) PCT No.: PCT/CN2019/079472

§ 371 Date: Dec. 5, 2019

(30) Foreign Application Priority Data
Jun. 14, 2018 (CN) 201810614838.8

(51) Int. Cl. G02B 5/20; G03F 7/00

(52) U.S. Cl. CPC G02B 5/201; G03F 7/0007

(57) ABSTRACT

A color film substrate, a method of manufacturing the color film substrate, a display panel and a display device are provided by the present disclosure. The color film substrate includes a plurality of color light-filtering units on a base substrate, at least one of the plurality of color light-filtering units includes N light-filtering sub-units, thicknesses of color filter layers of the N light-filtering sub-units are different, and N is an integer greater than 1.

### CROSS-REFERENCE TO RELATED APPLICATION

This application claims a priority to a Chinese Patent Application No. 201810614838.8 filed in China on Jun. 14, 2018, the disclosure of which is incorporated in its entirety by reference herein.

### TECHNICAL FIELD

The present disclosure relates to the field of display technology, and in particular, relates to a color film substrate, a method of manufacturing the color film substrate, a display panel and a display device.

### BACKGROUND

With development of a smart wearable product, a demand of a user for a wearable and display-enabled product gets prominent increasingly. A transflective display product such as a smart watch and the like has been generated. The transflective display product requires a low power consumption, and a driving circuit thereof is only switched between two voltage values, thereby achieving the low power consumption and displaying different color gamuts through a transmissive mode and a reflective mode.

### SUMMARY

A color film substrate, a method of manufacturing the color film substrate, a display panel and a display device are provided by the present disclosure.

In a first aspect, a color film substrate is provided in the present disclosure. The color film substrate includes a plurality of color light-filtering units on a base substrate, wherein at least one of the plurality of color light-filtering units includes N light-filtering sub-units, thicknesses of color filter layers of the N light-filtering sub-units are different, and N is an integer greater than 1.

Optionally, surfaces, parallel to the base substrate, of the N light-filtering sub-units are equal in area.

Optionally, the at least one color light-filtering unit includes a first light-filtering sub-unit and a second light-filtering sub-unit, and a thickness of a color filter layer of the first light-filtering sub-unit is greater than a thickness of a color filter layer of the second light-filtering sub-unit.

Optionally, a ratio of the thickness of the color filter layer of the first light-filtering sub-unit to the thickness of the color filter layer of the second light-filtering sub-unit is less than or equal to 2.

Optionally, the ratio of the thickness of the color filter layer of the first light-filtering sub-unit to the thickness of the color filter layer of the second light-filtering sub-unit is 1.2, 1.5 or 1.8.

Optionally, the color film substrate further includes a planarization layer covering the plurality of color light-filtering units, all positions of a surface of the planarization layer are equal in height.

Optionally, color filter layers of the N light-filtering sub-units are made of a non-photosensitive material.

Optionally, a black matrix is between two adjacent light-filtering sub-units of the N light-filtering sub-units.

Optionally, the first light-filtering sub-unit and the second light-filtering sub-unit are distributed alternately.

Optionally, a height of the black matrix is equal to a height of the second light-filtering sub-unit.

Optionally, the color film substrate further includes an alignment layer on the planarization layer.

In a second aspect, a method of manufacturing a color film substrate is further provided in the present disclosure. The method includes forming a plurality of color light-filtering units on a base substrate, wherein at least one of the plurality of color light-filtering units includes N light-filtering sub-units, thicknesses of color filter layers of the N light-filtering sub-units are different, and N is an integer greater than 1.

Optionally, the N light-filtering sub-units includes a first light-filtering sub-unit and a second light-filtering sub-unit; surfaces, parallel to the base substrate, of the first light-filtering sub-unit and the second light-filtering sub-unit are equal in area; a thickness of a color filter layer of the first light-filtering sub-unit is greater than a thickness of a color filter layer of the second light-filtering sub-unit, the method specifically includes: forming a color-filter material layer; coating a photoresist on the color-filter material layer, and exposing the photoresist by using a mask plate, wherein the mask plate includes a light-transmissible region, a light-proof region and a light semi-transmissible region; forming a photoresist-removed region corresponding to the light-transmissible region, a photoresist-completely-remained region corresponding to the light-proof region and a photoresist-partially-remained region corresponding to the light semi-transmissible region after a development is performed; etching the color-filter material layer in the photoresist-removed region; removing the photoresist in the photoresist-partially-remained region; etching a portion of the color-filter material layer in the photoresist-partially-remained region to form the second light-filtering sub-unit; removing the photoresist in the photoresist-completely-remained region to form the first light-filtering sub-unit.

Optionally, the N light-filtering sub-units includes a first light-filtering sub-unit and a second light-filtering sub-unit; surfaces, parallel to the base substrate, of the first light-filtering sub-unit and the second light-filtering sub-unit are equal in area; a thickness of a color filter layer of the first light-filtering sub-unit is greater than a thickness of a color filter layer of the second light-filtering sub-unit, the method specifically includes: forming a color-filter material layer; exposing the color-filter material layer by using a mask plate, wherein the mask plate includes a light-transmissible region, a light-proof region and a light semi-transmissible region; forming a color-filter-material layer removed region corresponding to the light-transmissible region, a color-filter-material-layer completely-remained region corresponding to the light-proof region, and a color-filter-material-layer partially-remained region corresponding to the light semi-transmissible region after a development is performed, wherein the color-filter material layer in the color-filter-material-layer completely-remained region is formed as the first light-filtering sub-unit, and the color-filter-material-layer in the color-filter-material-layer partially-remained region is formed as the second light-filtering sub-unit.

Optionally, the plurality of color light-filtering units is formed on the base substrate, the method further includes: forming a planarization layer covering the plurality of color light-filtering units, wherein all positions of a surface of the planarization layer are equal in height.

Optionally, the color filter layer is made of a photosensitive material.

In a third aspect, a display panel is provided in the present disclosure. The display panel includes the color film substrate according to the first aspect, and an array substrate opposite to the color film substrate, wherein the array substrate includes a plurality of sub-pixels, and the plurality of sub-pixels corresponds to the plurality of color light-filtering units in a one-to-one manner.

Optionally, the sub-pixels are reflective sub-pixels or transmissible sub-pixels.

Optionally, each of the plurality of sub-pixels includes N display units corresponding to N light-filtering sub-units in a one-to-one manner, each of the N display units includes a driving thin film transistor.

In a fourth aspect, a display device is provided in the present disclosure. The display device includes the display panel according to the third aspect.

### BRIEF DESCRIPTION OF THE DRAWINGS

FIGS. 1A and 1B are schematic views of a display panel according to some embodiments of the present disclosure;

FIGS. 2 to 8 are process schematic views of manufacturing a color film substrate according to some embodiments of the present disclosure; and

FIGS. 9-10 are flow charts of a method of manufacturing a color film substrate according to some embodiments of the present disclosure.

### REFERENCE NUMERALS

1. base substrate 2. color light-filtering unit 21. first light-filtering sub-unit 22. second light-filtering sub-unit 3. planarization 4. array substrate 5. black matrix 6, 8. mask plate 7. color filter layer 81. light-transmissible region 82. light semi-transmissible region 83. light-proof region 91, 92. alignment layer 10. display unit 11. sub-pixel

### DETAILED DESCRIPTION

In order to make objects, technical solutions and advantages of the embodiments of the present disclosure clearer, technical solutions of the embodiments of the present disclosure will be clearly and completely described below in conjunction with drawings of the embodiments of the present disclosure.

A color film substrate, a method of manufacturing the color film substrate, a display panel and a display device are provided by some embodiments of the present disclosure. The solutions of the present disclosure make a manufacturing process of the color film substrate simpler, and may realize that the display device may display more colors at a lower power consumption.

The color film substrate provided by some embodiments of the present disclosure includes a plurality of color light-filtering units on a base substrate. At least one of the plurality of color light-filtering units includes N light-filtering sub-units, thicknesses of color filter layers of the N light-filtering sub-units are different, and N is an integer greater than 1.

In some embodiments, at least one color light-filtering unit of the color film substrate is divided into a plurality of light-filtering sub-units, and thicknesses of the color filter layers of the different light-filtering sub-units are different. Thus, brightnesses of light emitted through different light-filtering sub-units of the same color light-filtering unit are different, so that the display device including the color film substrate may display more colors at a lower power consumption.

For example, in order to realize a 64-color display, each sub-pixel of a transflective display product is divided into two display units, and areas of the two display units are not equal. For example, an area ratio between areas of the two display units is 1:2, and each of the two display units is driven by a thin film transistor, but in such a case, a manufacturing process of the display product to be complicated, and a storage capacitance of the display unit having a relatively smaller area is relatively small, which may easily cause a defect such as a splash screen.

Thus, optionally, surfaces of the N light-filtering sub-units parallel to the base substrate in the embodiments are equal in area. In this way, an area of a specific light-filtering sub-unit will not be too small, a manufacturing process thereof is simple, and implementation thereof is easy. It may be ensured that a storage capacitance of a display unit corresponding to each light-filtering sub-unit is not too small, thereby avoiding the defect such as the splash screen.

In some embodiments of the present disclosure, the number of light-filtering sub-units included in each color light-filtering unit may be determined according to the number of colors to be displayed. The greater the number of light-filtering sub-units included in each color light-filtering unit is, the more colors may be displayed, but at the same time, a complexity of the manufacturing process thereof will be increased.

In some specific embodiments, each of the color light-filtering units includes a first light-filtering sub-unit and a second light-filtering sub-unit. A thickness of a color filter layer of the first light-filtering sub-unit is greater than a thickness of a color filter layer of the second light-filtering sub-unit. Thus, each sub-pixel of the display device including the color film substrate may realize a four-color display by using 2-bit pixel data. In the case that a pixel includes three sub-pixels, the pixel may achieve a 64-color display.

Optionally, a ratio of the thickness of the color filter layer of the first light-filtering sub-unit to the thickness of the color filter layer of the second light-filtering sub-unit is less than or equal to 2, which enables the color display to be relatively balanced.

When a color gamut needs to be adjusted, the ratio of the thickness of the color filter layer of the first light-filtering sub-unit to the thickness of the color filter layer of the second light-filtering sub-unit may be adjusted, such that the ratio of the thickness of the color filter layer of the first light-filtering sub-unit to the thickness of the color filter layer of the second light-filtering sub-unit is 1.2, 1.5 or 1.8.

Optionally, the color film substrate further includes a planarization layer covering the color light-filtering unit, and all positions of a surface of the planarization layer are equal in height. Thus, when the surface of the planarization layer is coated with a polyimide solution subsequently, a problem of a polyimide being incompletely coated does not occur, and a problem that the polyimide is difficult to be coated may be overcome.

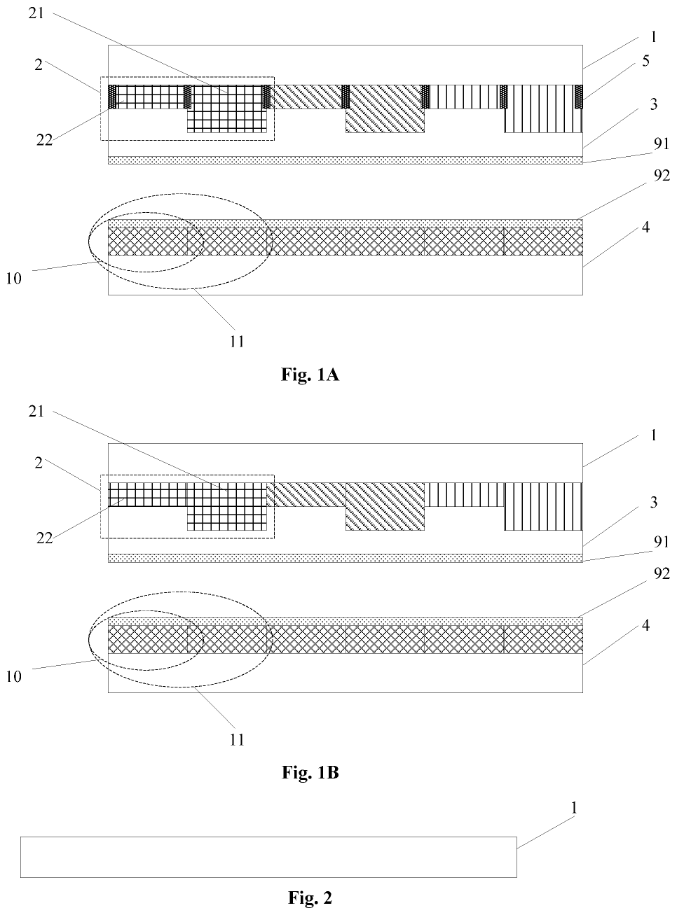

In some specific embodiments, as shown in FIG. 1A, the color film substrate includes the base substrate 1 and a black matrix 5 on the base substrate 1. The black matrix 5 defines the plurality of color light-filtering units 2, and each color light-filtering unit 2 includes the first light-filtering sub-unit 21 and the second light-filtering sub-unit 22. The thickness of the color filter layer of the first light-filtering sub-unit 21 is greater than the thickness of the color filter layer of the second light-filtering sub-unit 22. The color film substrate further includes the planarization layer 3 covering the color light-filtering unit 2 and an alignment layer 91 on the planarization layer 3, and all positions of the surface of the planarization layer 3 are equal in height.

Optionally, in order to increase an aperture ratio, the color film substrate maybe not provided with the black matrix 5. As shown in FIG. 1B, the color film substrate may include the base substrate 1 and the plurality of color light-filtering units 2 on the base substrate 1. Each color light-filtering unit 2 includes the first light-filtering sub-unit 21 and the second light-filtering sub-unit 22, and the thickness of the color filter layer of the first light-filtering sub-unit 21 is greater than the thickness of the color filter layer of the second light-filtering sub-unit 22. The color film substrate further includes the planarization layer 3 covering the color light-filtering unit 2 and the alignment layer 91 on the planarization layer, and all positions of the surface of the planarization layer are equal in height.

A method of manufacturing the color film substrate is provided by some embodiments of the present disclosure. The method of manufacturing the color film substrate may be used to manufacture the color film substrate as shown in FIG. 1A or FIG. 1B. The method of manufacturing the color film substrate includes: forming a plurality of color light-filtering units on a base substrate, wherein each of the color light-filtering units includes N light-filtering sub-units, thicknesses of color filter layers of the N light-filtering sub-units are different, and N is an integer greater than 1.

In some embodiments, each of the color light-filtering units of the manufactured color film substrate is divided into the plurality of light-filtering sub-units, and the thicknesses of the color filter layers of the different light-filtering sub-units are different. Thus, the brightnesses of light emitted through the different light-filtering sub-units of the same color light-filtering unit are different, so that the display device including the color film substrate may display more colors at the lower power consumption.

In order to realize a 64-color display, each sub-pixel of a transflective display product is divided into two display units, and areas of the two display units are not equal. For example, an area ratio between areas of the two display units is 1:2, and each of the two display units is driven by a thin film transistor, but in such a case, a manufacturing process of the display product to be complicated, and a storage capacitance of the display unit having a relatively smaller area is relatively small, which may easily cause a defect such as a splash screen.

Optionally, surfaces of the N light-filtering sub-units parallel to the base substrate in the embodiments are equal in area. In this way, an area of a specific light-filtering sub-unit will not be too small, a manufacturing process thereof is simple, and implementation thereof is easy. It may be ensured that a storage capacitance of a display unit corresponding to each light-filtering sub-unit is not too small, thereby avoiding the defect such as the splash screen.

In some specific embodiments, each of the color light-filtering units includes a first light-filtering sub-unit and a second light-filtering sub-unit. A thickness of a color filter layer of the first light-filtering sub-unit is greater than a thickness of a color filter layer of the second light-filtering sub-unit. Thus, each sub-pixel of the display device including the color film substrate may realize a four-color display by using 2-bit pixel data. In the case that a pixel includes three sub-pixels, the pixel may achieve a 64-color display.

Optionally, when surfaces, parallel to the base substrate, of the first light-filtering sub-unit and the second light-filtering sub-unit are equal in area and the color filter layers are made of a non-photosensitive material, the method of manufacturing the color film substrate specifically includes steps S11-S17.

S11: forming a color-filter material layer;

S12: coating a photoresist on the color-filter material layer, and exposing the photoresist by using a mask plate, wherein the mask plate includes a light-transmissible region, a light-proof region and a light semi-transmissible region;

S13: forming a photoresist-removed region corresponding to the light-transmissible region, a photoresist-completely-remained region corresponding to the light-proof region and a photoresist-partially-remained region corresponding to the light semi-transmissible region after a development is performed;

S14: etching the color-filter material layer in the photoresist-removed region;

S15: removing the photoresist in the photoresist-partially-remained region;

S16: etching a portion of the color-filter material layer in the photoresist-partially-remained region to form the second light-filtering sub-unit;

S17: removing the photoresist in the photoresist completely remained region to form the first light-filtering sub-unit.

In another specific embodiment, when surfaces, parallel to the base substrate, of the first light-filtering sub-unit and the second light-filtering sub-unit are equal in area and the color filter layer is made of a non-photosensitive material, the method of manufacturing the color film substrate specifically includes steps S21-S23.

S21: forming a color-filter material layer;

S22: exposing the color-filter material layer by using a mask plate, wherein the mask plate includes a light-transmissible region, a light-proof region and a light semi-transmissible region;

S23: forming a color-filter-material-layer removed region corresponding to the light-transmissible region, a color-filter-material-layer completely-remained region corresponding to the light-proof region, and a color-filter-material-layer partially-remained region corresponding to the light semi-transmissible region after a development is performed, wherein the color-filter material layer in the color-filter-material-layer completely-remained region is formed as the first light-filtering sub-unit, and the color-filter material layer in the color-filter-material-layer partially-remained region is formed as the second light-filtering sub-unit.

Optionally, after forming the color light-filtering unit, the method further includes: forming the planarization layer covering the color light-filtering unit, wherein all positions of the surface of the planarization layer are equal in height.

Thus, when the surface of the planarization layer is coated with a polyimide solution subsequently, a problem of a polyimide being incompletely coated does not occur, and a problem that the polyimide is difficult to be coated may be overcome.

As shown in FIG. 2 to FIG. 8, taking, as an example, a case of forming a color light-filtering unit having a type of color, the method of manufacturing the color film substrate specifically includes following steps S31-S37.

S31: as shown in FIG. 2, providing the base substrate 1 and cleaning the base substrate 1.

The base substrate 1 may be a glass substrate or a quartz substrate. Specifically, the base substrate 1 may be cleaned by using a high-pressure water gun to remove impurities and fine particles on a surface of the base substrate 1.

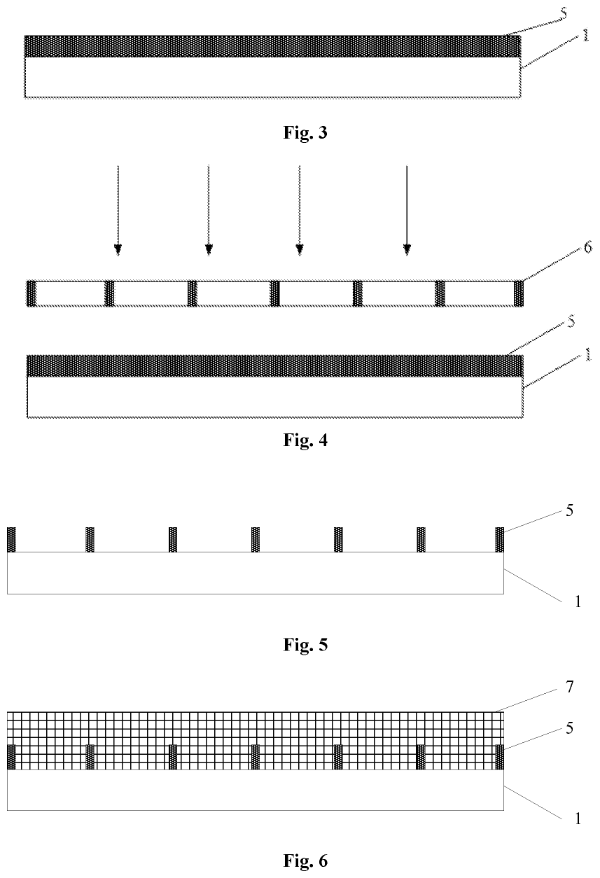

S32: as shown in FIG. 3, forming the black matrix 5 on the base substrate 1.

The black matrix 5 may be made of a negative photoresist material, and a portion, irradiated by ultraviolet light, of the negative photoresist material may be cured, and a portion, not irradiated by the ultraviolet light, of the negative photoresist material is removed after a development is performed.

S33: as shown in FIG. 4, exposing the black matrix 5 using a mask plate 6.

The mask plate 6 includes a light-transmissible region and a light-proof region, and the black matrix 5 may be irradiated by the ultraviolet light through the light-transmissible region.

S34: as shown in FIG. 5, forming a pattern of the black matrix 5 after a development is performed.

The portion irradiated by the ultraviolet light may be retained after the development is performed, and the portion not irradiated by the ultraviolet light is removed after the development is performed.

S35: as shown in FIG. 6, coating the color filter layer 7 on the base substrate 1.

The color filter layer 7 may be one of a red color filter layer, a blue color filter layer or a green color filter layer, and the color filter layer 7 may be made of the negative photoresist material.

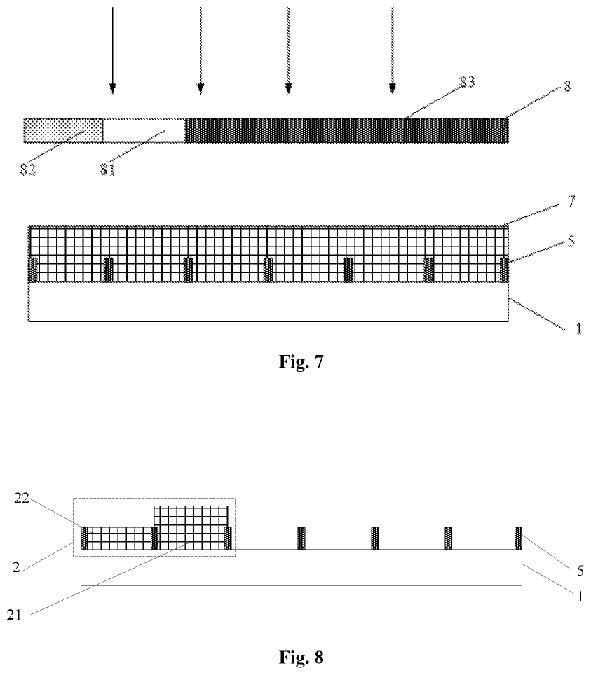

S36: as shown in FIG. 7, exposing the color filter layer 7 using a mask plate 8.

The mask plate 8 includes a light-transmissible region 81, a light semi-transmissible region 82 and a light-proof region 83;

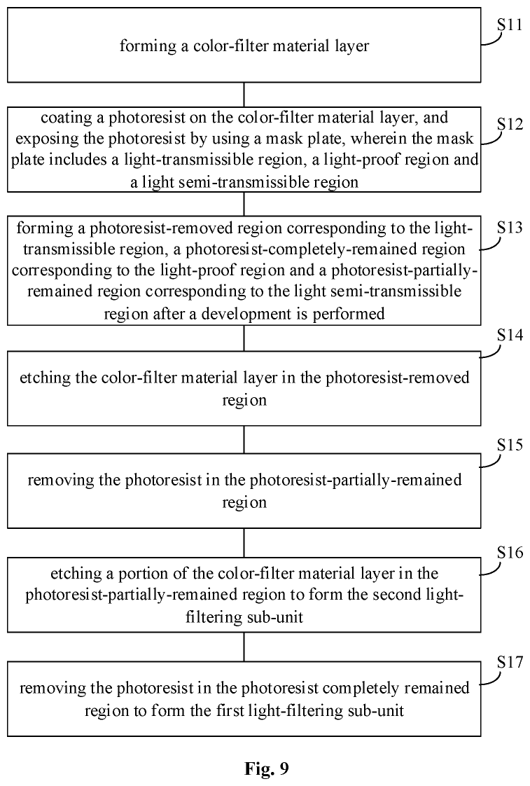

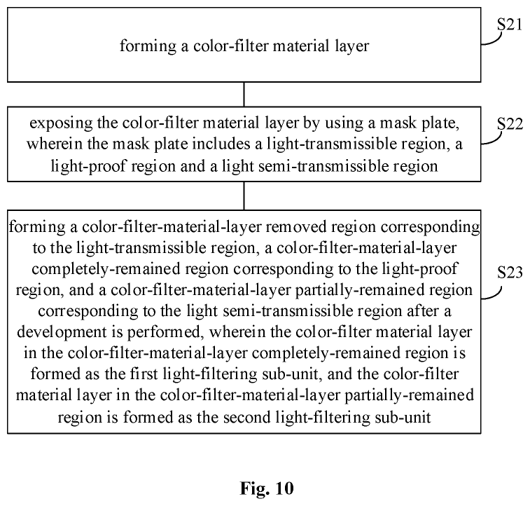

S37: as shown in FIG. 8, forming the color light-filtering unit 2 after a development is performed.

After the development is performed, a portion, corresponding to the light-proof region, of the color filter layer 7 is removed; a portion, corresponding to the light semi-transmissible region, of the color filter layer 7 is removed to form the second light-filtering sub-unit 22; and a portion, corresponding to the light-transmissible region, of the color filter layer 2 is retained to form the first light-filtering sub-unit 21.

The thicknesses of the first light-filtering sub-unit 21 and the second light-filtering sub-unit 22 may be adjusted by adjusting exposure amounts. A process of manufacturing of color light-filtering units having other colors only needs to repeat the steps S35-S37.

It may be seen that the method of manufacturing the color film substrate of the present disclosure is simple in process. A color light-filtering unit including color filter layers with different thicknesses may be manufactured by exposing the color filter layers using a halftone mask plate. Compared with a design of a display panel in a related art, an optical performance of the color film substrate of the present disclosure is improved, an electrical performance of the color film substrate of the present disclosure may meet a requirement, and related defects are avoided.

A display panel is provided by some embodiments of the present disclosure. The display panel includes the color film substrate as described above and an array substrate opposite to the color film substrate. As shown in FIG. 1A and FIG. 1B, the array substrate includes the plurality of sub-pixels 11, the plurality of sub-pixels 11 is covered with an alignment layer 92, and each of the plurality of sub-pixels 11 corresponds to one of the plurality of color light-filtering units 2.

In the present disclosure, at least one color light-filtering unit of the color film substrate is divided into the plurality of light-filtering sub-units, and thicknesses of color filter layers of the different light-filtering sub-units are different. Thus, the brightnesses of light emitted through the different light-filtering sub-units of the same color light-filtering unit are different, so that the display device including the color film substrate may display more colors at the lower power consumption.

Optionally, the sub-pixels are reflective sub-pixels or transmissible sub-pixels. That is, the display panel of the present disclosure may be any one of a transflective display panel, a transmissible display panel or a reflective display panel.

Optionally, each of the plurality of sub-pixels includes N display units corresponding to N light-filtering sub-units in a one-to-one manner, each of the N display units includes a driving thin film transistor. When a display is performed, the driving thin film transistor receives inputted pixel data, and drives, according to the inputted pixel data, a corresponding display unit to display.

In a case that a value of N is 2 and the inputted pixel data is 2-bit data, since each color light-filtering unit includes two light-filtering sub-units with different thicknesses, each sub-pixel may realize a display having 4 gray scales. In a case that the display panel includes sub-pixels having three colors, a 64-color display may be realized.

In some specific embodiments, as shown in FIG. 1A, the display panel includes the color film substrate and the array substrate opposite to the color film substrate to form a cell. The color film substrate includes the base substrate 1 and the black matrix 5 on the base substrate 1. The black matrix 5 defines the plurality of color light-filtering units 2, and each color light-filtering unit 2 includes the first light-filtering sub-unit 21 and the second light-filtering sub-unit 22. The thickness of the color filter layer of the first light-filtering sub-unit 21 is greater than the thickness of the color filter layer of the second light-filtering sub-unit 22. The color film substrate further include the planarization layer 3 covering the color light-filtering unit 2 and the alignment layer 91 on the planarization layer 3, and all positions of the surface of the planarization layer 3 is equal in height. The array substrate includes sub-pixels 11 corresponding to the color light-filtering units 2 in a one-to-one manner. Each of the sub-pixels 11 includes two display units 10, and each display unit 10 includes a driving thin film transistor. When the display is performed, the driving thin film transistor receives the inputted pixel data, and drives, according to the inputted pixel data, the corresponding display unit 10 to display.

Optionally, in order to increase the aperture ratio, the color film substrate may not be provided with the black matrix 5. As shown in FIG. 1B, the color film substrate may include the base substrate 1 and the plurality of color light-filtering units 2 on the base substrate 1. Each color light-filtering unit 2 includes the first light-filtering sub-unit 21 and the second light-filtering sub-unit 22, and the thickness of the color filter layer of the first light-filtering sub-unit 21 is greater than the thickness of the color filter layer of the second light-filtering sub-unit 22. The color film substrate further includes the planarization layer 3 covering the color light-filtering unit 2 and the alignment layer on the planarization layer, and all positions of the surface of the planarization layer 3 are equal in height. The array substrate includes sub-pixels 11 corresponding to the color light-filtering units 2 in a one-to-one manner. The sub-pixel 11 includes two display units 10, and each display unit 10 includes a driving thin film transistor. When the display is performed, the driving thin film transistor receives the inputted pixel data, and drives, according to the inputted pixel data, the corresponding display unit 10 to display.

In the case that the display panel of the present disclosure is the light-transmissible display panel, each of the light-transmissible sub-pixels is divided into N portions. Each portion includes a light-filtering sub-unit and a display unit corresponding to the light-filtering sub-unit. When the display panel performs display, since the thicknesses of the different color filter layers of light-filtering sub-units in the same light-transmissible sub-pixel are different, the brightnesses of light emitted through different portions of the same light-transmissible sub-pixel are different, so that the display panel may display more colors at a lower power consumption.

In the case that the display panel of the present disclosure is a reflective display panel, each of reflective sub-pixels is divided into N portions. Each portion includes a light-filtering sub-unit and a display unit corresponding to the light-filtering sub-unit. When the display panel performs display, since the thicknesses of the different color filter layers of light-filtering sub-units in the same reflective sub-pixel are different, the brightnesses of light emitted through different portions of the same reflective sub-pixel are different, so that the display panel may display more colors at a lower power consumption.

In the case that the display panel of the present disclosure is a transreflective display panel, each of reflective sub-pixels is divided into N portions. Each portion includes a light-filtering sub-unit and a display unit corresponding to the light-filtering sub-unit. When the display panel performs display, since the thicknesses of the different color filter layers of light-filtering sub-units in the same reflective sub-pixel are different, the brightnesses of light emitted through different portions of the same reflective sub-pixel are different. Each of transmissible sub-pixels is divided into N portions. Each portion includes a light-filtering sub-unit and a display unit corresponding to the light-filtering sub-unit. When the display panel performs display, since the thicknesses of the different color filter layers of light-filtering sub-units in the same transmissible sub-pixel are different, the brightnesses of light emitted through different portions of the same transmissible sub-pixel are different. Thus, the display panel may display more colors at a lower power consumption.

A display device is also provided by some embodiments of the present disclosure. The display device includes the display panel as described above. The display device may be any product or component having a display function, such as a liquid crystal television, a liquid crystal display, a digital photo frame, a mobile phone, a tablet computer, or the like. The display device further includes a flexible circuit board, a printed circuit board and a back plate.

In the embodiments of the present disclosure, numbering of steps does not necessarily define a sequence of the steps. Variation of an order of the steps also falls into the protection scope of the present disclosure for one of ordinary skills in the art without paying creative work.

Unless otherwise defined, technical terms or scientific terms used in the present disclosure should be interpreted according to common meanings thereof as commonly understood by those of ordinary skills in the art to which the present disclosure belongs. Such terms as “first”, “second” and the like used in the present disclosure do not represent any order, quantity or importance, but are merely used to distinguish different components. Such terms as “including”, or “comprising” and the like mean that an element or an article preceding the term contains elements or items and equivalents thereof behind the term, but does not exclude other elements or items. Such terms as “connect”, or “interconnect” and the like are not limited to physical or mechanical connections, but may include electrical connections, whether direct connection or indirect connection. Such terms as “on”, “under”, “left”, “right” and the like are only used to represent a relative position relationship, and when an absolute position of a described object is changed, the relative position relationship thereof may also be changed accordingly.

It may be understood that when an element such as a layer, a film, a region or a substrate is referred to as being “on” or “under” another element, the element may be “directly” “on” or “under” the another element, or there may exist an intervening element.

The above embodiments are merely optional embodiments of the present disclosure. It should be noted that numerous improvements and modifications may be made by those skilled in the art without departing from the principle of the present disclosure, and these improvements and modifications shall also fall within the scope of the present disclosure.

1. A color film substrate, comprising:
a plurality of color light-filtering units on a base substrate,
wherein at least one of the plurality of color light-filtering units comprises N light-filtering sub-units, thicknesses of color filter layers of the N light-filtering sub-units are different, and N is an integer greater than 1.

2. The color film substrate according to claim 1, wherein surfaces, parallel to the base substrate, of the N light-filtering sub-units are equal in area.

3. The color film substrate according to claim 1, wherein the at least one color light-filtering unit comprises a first light-filtering sub-unit and a second light-filtering sub-unit, and a thickness of a color filter layer of the first light-filtering sub-unit is greater than a thickness of a color filter layer of the second light-filtering sub-unit.

4. The color film substrate according to claim 3, wherein a ratio of the thickness of the color filter layer of the first light-filtering sub-unit to the thickness of the color filter layer of the second light-filtering sub-unit is less than or equal to 2.

5. The color film substrate according to claim 4, wherein the ratio of the thickness of the color filter layer of the first light-filtering sub-unit to the thickness of the color filter layer of the second light-filtering sub-unit is 1.2, 1.5 or 1.8.

6. The color film substrate according to claim 1, further comprising:
a planarization layer covering the plurality of color light-filtering units, all positions of a surface of the planarization layer are equal in height.

7. The color film substrate according to claim 1, wherein color filter layers of the N light-filtering sub-units are made of a non-photosensitive material.

8. The color film substrate according to claim 1, wherein a black matrix is between two adjacent light-filtering sub-units of the N light-filtering sub-units.

9. The color film substrate according to claim 3, wherein the first light-filtering sub-unit and the second light-filtering sub-unit are distributed alternately.

10. The color film substrate according to claim 3, wherein a black matrix is arranged between two adjacent light-filtering sub-units of the N light-filtering sub-units, and a height of the black matrix is equal to a height of the second light-filtering sub-unit.

11. The color film substrate according to claim 6, further comprising:
an alignment layer on the planarization layer.

12. A method of manufacturing a color film substrate, comprising:
forming a plurality of color light-filtering units on a base substrate, wherein at least one of the plurality of color light-filtering units comprises N light-filtering sub-units, thicknesses of color filter layers of the N light-filtering sub-units are different, and N is an integer greater than 1.

13. The method of manufacturing the color film substrate according to claim 12, wherein the N light-filtering sub-units comprises a first light-filtering sub-unit and a second light-filtering sub-unit,
surfaces, parallel to the base substrate, of the first light-filtering sub-unit and the second light-filtering sub-unit are equal in area,
a thickness of a color filter layer of the first light-filtering sub-unit is greater than a thickness of a color filter layer of the second light-filtering sub-unit, the method specifically comprises:
forming a color-filter material layer,
coating a photoresist on the color-filter material layer, and exposing the photoresist by using a mask plate, wherein the mask plate comprises a light-transmissible region, a light-proof region and a light semi-transmissible region;
forming a photoresist-removed region corresponding to the light-transmissible region, a photoresist-completely-remained region corresponding to the light-proof region and a photoresist-partially-remained region corresponding to the light semi-transmissible region after a development is performed;
etching the color-filter material layer in the photoresist-removed region;
removing the photoresist in the photoresist-partially-remained region;
etching a portion of the color-filter material layer in the photoresist-partially-remained region to form the second light-filtering sub-unit;
removing the photoresist in the photoresist-completely-remained region to form the first light-filtering sub-unit.

14. The method of manufacturing the color film substrate according to claim 12, wherein the N light-filtering sub-units comprises a first light-filtering sub-unit and a second light-filtering sub-unit,
surfaces, parallel to the base substrate, of the first light-filtering sub-unit and the second light-filtering sub-unit are equal in area, a thickness of a color filter layer of the first light-filtering sub-unit is greater than a thickness of a color filter layer of the second light-filtering sub-unit, the method specifically comprises:
forming a color-filter material layer,
exposing the color-filter material layer by using a mask plate, wherein the mask plate comprises a light-transmissible region, a light-proof region and a light semi-transmissible region;
forming a color-filter-material layer removed region corresponding to the light-transmissible region, a color-filter-material-layer completely-remained region corresponding to the light-proof region, and a color-filter-material-layer partially-remained region corresponding to the light semi-transmissible region after a development is performed, wherein the color-filter material layer in the color-filter-material-layer completely-remained region is formed as the first light-filtering sub-unit, and the color-filter-material-layer in the color-filter-material-layer partially-remained region is formed as the second light-filtering sub-unit.

15. The method of manufacturing the color film substrate according to claim 12, wherein the plurality of color light-filtering units is formed on the base substrate, the method further comprises:
forming a planarization layer covering the plurality of color light-filtering units, wherein all positions of a surface of the planarization layer are equal in height.

16. The method of manufacturing the color film substrate according to claim 12, wherein the color filter layer is made of a photosensitive material.

17. A display panel, comprising:
the color film substrate according to claim 1, and
an array substrate opposite to the color film substrate, wherein the array substrate comprises a plurality of sub-pixels, and the plurality of sub-pixels corresponds to the plurality of color light-filtering units in a one-to-one manner.

18. The display panel according to claim 17, wherein the sub-pixels are reflective sub-pixels or transmissible sub-pixels.

19. The display panel according to claim 17, wherein,
each of the plurality of sub-pixels comprises N display units corresponding to N light-filtering sub-units in a one-to-one manner, each of the N display units comprises a driving thin film transistor.

20. A display device comprising:
the display panel according to claim 17.
